(19) United States
(12) Patent Application Publication
(10) Pub. No.: US 2008/0143347 A1
(43) Pub. Date: Jun. 19, 2008

(54) METHOD AND APPARATUS FOR SENSING COMPOSITION OF FLEXIBLE FUELS

(75) Inventors: GARY CASEY, Thousand Oaks, CA (US); SALEH AHMED, SIMI VALLEY, CA (US)

Correspondence Address: JEFFER, MANGELS, BUTLER & MARMARO, LLP, 1900 AVENUE OF THE STARS, 7TH FLOOR, LOS ANGELES, CA, 90067, US

(73) Assignee: KAVLICO CORPORATION, Moorpark, CA (US)

(21) Appl. No.: 11/611,804

(22) Filed: Dec. 15, 2006

(51) Int. Cl. G01R 27/26

(52) U.S. Cl. 324/663

(57) ABSTRACT

The composition of a fluid is measured with a sensor with a tube having: (i) a cavity for holding contents therein; and (ii) at least one opening in the tube being in communication with the cavity of the tube and the content held therein. The sensor further includes a sensor body attached to the tube having: (i) a circuit board; and (ii) a header, the header comprising a plurality of contacts that are electrically coupled to the circuit board; wherein the plurality of contacts of the header are in communication with the cavity of the tube. A method for measuring the composition of the fluid using the sensor is also described.

### BACKGROUND

1. Field

The present invention relates generally to sensors, and more particularly, to a method and apparatus for sensing composition of flexible fuels.

2. Background

Flexible fuel, which is a blend of ethanol and gasoline, is becoming more common as a viable alternative energy source for vehicle operation. Flexible fuel vehicles (FFVs) are designed to run on gasoline or a blend of up to 85% ethanol (commonly referred to as “E85” with the number behind the “E” designating the percentage of ethanol that is in the fuel).

FFVs have been produced since the 1980s, and dozens of models are currently available. FFVs experience no loss in performance when operating on flex fuel. However, since a gallon of ethanol contains less energy than a gallon of gasoline, FFVs typically get about 20-30% fewer miles per gallon when fueled with E85. Except for a few engine and fuel system modifications, FFVs are identical to gasoline-only models.

For example, with flex fuel, there is a need to determine the content of the fuel;

more specifically, the ratio of the blend of ethanol to gasoline in the fuel. This information is required to calculate the correct air/fuel ratio for fuel metering and other parameters to optimize engine performance. The information may also be used as an indicator to warn the user regarding the content of the fuel. It would be desirable to be able to determine the content information to be used for automotive and other industrial applications.

### SUMMARY OF THE PREFERRED EMBODIMENTS

In one preferred embodiment of the present invention, the composition of a fluid is measured with a sensor with a tube having: (i) a cavity for holding contents therein;

and (ii) at least one opening in the tube being in communication with the cavity of the tube and the content held therein. The sensor further includes a sensor body attached to the tube having: (i) a circuit board; and (ii) a header, the header comprising a plurality of pins that are electrically coupled to the circuit board; wherein the plurality of pins of the header are in communication with the cavity of the tube.

In another preferred embodiment of the present invention, a method is provided for determining the composition of a fluid having a first component and a second component, each component having a respective dielectric property. The method includes the steps of providing a sensor having a capacitative sense element; putting the fluid in contact with the capacitative sense element; determining a dielectric property of the fluid based on the capacitance of the capacitative sense element; and, determining the proportion of at least one of the first component and the second component.

In yet another embodiment of the present invention, an apparatus for determining the composition of a fluid having a first component and a second component, each component having a respective dielectric property, comprises a container for holding the fluid; a capacitative sense element, the capacitative sense element having a plurality of pins placed in contact with the fluid in the container; and, a circuit coupled to the capacitative sense element, the circuit configured to determine a dielectric property of the fluid based on a capacitance of the capacitative sense element.

Other objects, features and advantages will become apparent to those skilled in the art from the following detailed description. It is to be understood, however, that the detailed description and specific examples, while indicating exemplary embodiments, are given by way of illustration and not limitation. Many changes and modifications within the scope of the following description may be made without departing from the spirit thereof, and the description should be understood to include all such variations.

### BRIEF DESCRIPTION OF THE DRAWINGS

The invention may be more readily understood by referring to the accompanying drawings in which:

FIG. 1 is a first perspective view of a fuel sensor configured in accordance with one preferred embodiment of the present invention;

FIG. 2 is a second perspective view of the fuel sensor of FIG. 1;

FIG. 3 is a front plan view of the fuel sensor of FIG. 1;

FIG. 4 is a side plan view of the fuel sensor of FIG. 1;

FIG. 5 is a top plan view of the fuel sensor of FIG. 1;

FIG. 6 is a cross-sectional view of the fuel sensor of FIG. 1, taken along line VI-VI of FIG. 5;

FIG. 7 is a cross-sectional view of the fuel sensor of FIG. 1, taken along line VII-VII of FIG. 5;

FIG. 8 is a detailed top plan view of a sensor electronics housing portion of the fuel sensor of FIG. 1, configured in accordance with one preferred embodiment of the present invention;

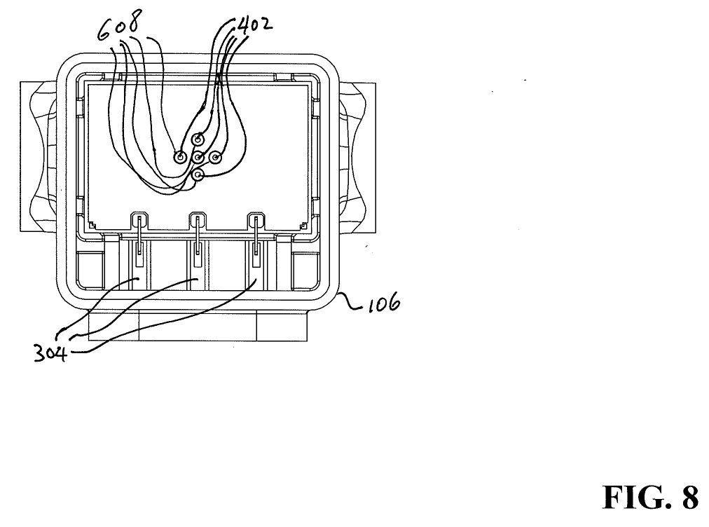

FIG. 9 is a perspective view of a header of the fuel sensor of FIG. 1, configured in accordance with one preferred embodiment of the present invention;

FIG. 10 is a top plan view of the header of the fuel sensor of FIG. 1;

FIG. 11 is a cross-sectional view of the header of FIG. 10, taken along line XI-XI of FIG. 10;

FIG. 12 is a cross-sectional view of the header of FIG. 10, taken along line XII-XII of FIG. 10;

FIG. 13 is a top plan view of a circuit board of the fuel sensor of FIG. 1, configured in accordance with one preferred embodiment of the present invention;

FIG. 14 is a bottom plan view of the circuit board of FIG. 13 ; and,

FIG. 15 is a side view of the circuit board of FIG. 13.

Like numerals refer to like parts throughout the several views of the drawings.

### DETAILED DESCRIPTION OF THE PREFERRED EMBODIMENTS

The present invention is directed to a fuel sensor for determining the composition of flexible fuel. In one preferred embodiment, the flex fuel sensor determines the composition of the flex fuel (i.e., mixture of how much ethanol versus gasoline is in the mixture) via the use of a dielectric measurement. The flex fuel sensor incorporates a header, which consists of a metal, glass, and pin assembly, that is immersed in the flex fuel as a capacitive probe. Specifically, the pins of the header function as the electrodes. As the fluid passes through the pins of the header, the capacitance will change in proportion to the dielectric of the fluid and used to determine the composition of the flex fuel.

The dielectric constant (DC) of gasoline and ethanol is 2.2 and 24.2 respectively. This large difference between the two fluids, and in conjunction with their non-conductive properties, lends itself to utilize a dielectric measurement method as the viable means to discriminate between the amount of the components of the two. In one preferred embodiment of the present invention, a linear transfer function can be used to determine the constituents. Any value of DC between the two extremes (2.2 and 24) can then be used as an indicator to determine the fuel's respective constituents. As discussed herein, the shorthand of “E%” will be used to represent the percentage of ethanol that is in the flexible fuel, where the “%” is the number. Thus, E85 represents a flexible fuel mixture of 85% ethanol and 15% gasoline. Any proportion between E0 to E100 can be interpolated using a linear transfer function. For example, a DC value of 5.5 will represent E15, and 20.9 will represent E85. In one preferred embodiment of the present invention, the formula used to determine DC based on the percentage of ethanol, or

DC=0.22E+2.2

where E represents ethanol content and it will vary from 0 for E0, to 100 for E100.

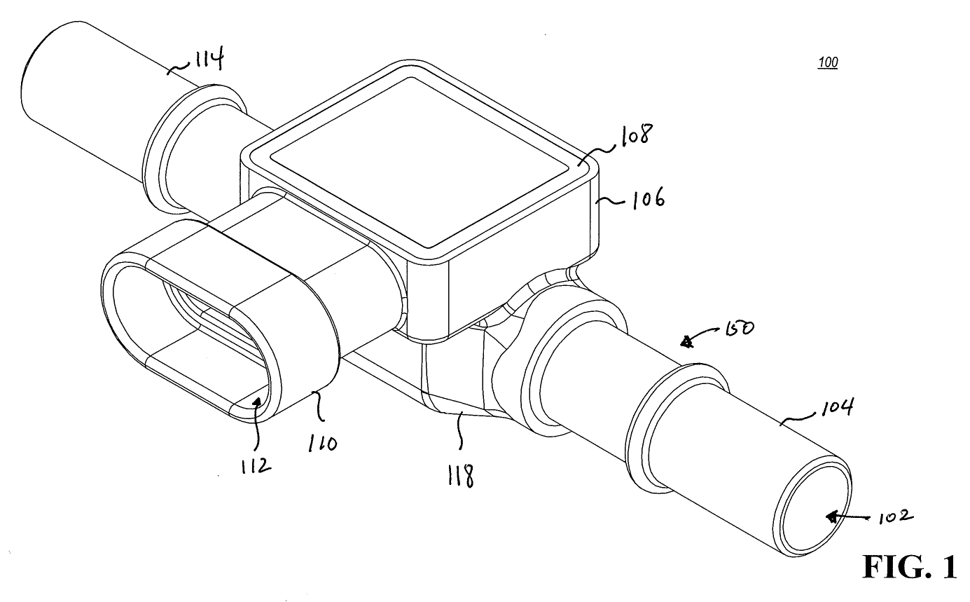

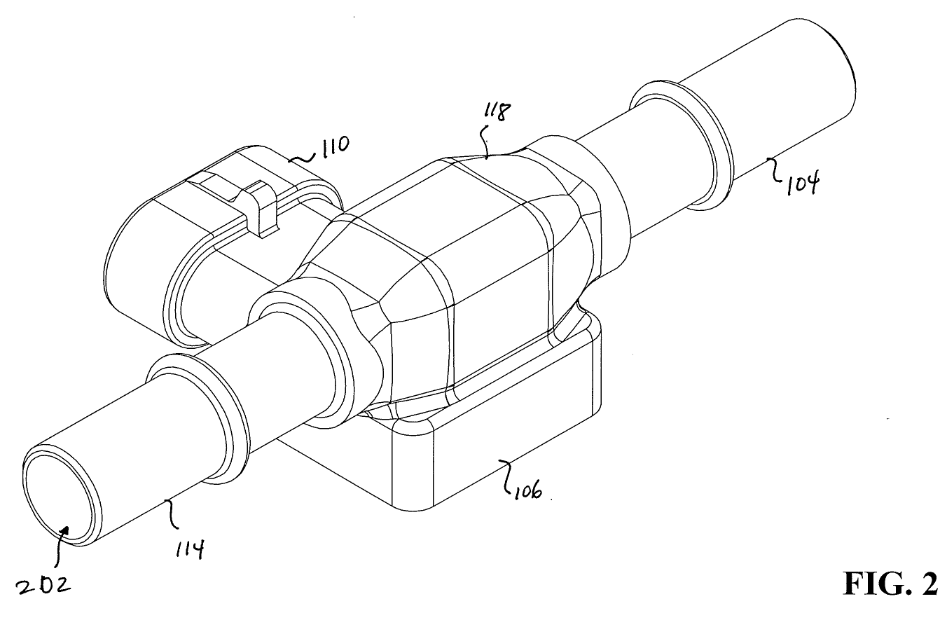

FIGS. 1 and 2 illustrate two perspective views of a fuel sensor 100. In one preferred embodiment of the present invention, the fuel sensor 100 is configured so that it can be mounted directly in the path through which the fuel travels, such as in a fuel line, fuel tank, fuel rail, etc. The fuel sensor 100 includes a fuel tube 150 having a pair of inlet/outlet tubes 104, 114 and a center portion 118. In one preferred embodiment of the present invention, the tubes 104, 114 are used to attach to a fuel line. The fuel flows through a tube openings 102 in tube 104 and a tube opening 202 in tube 114. In one preferred embodiment of the present invention, the tube is a cylindrical structure, as illustrated in the figure. In other preferred embodiments, the tube may be a structure with other cross-sectional shapes such that it is a hollow body that may be used for conveying or containing liquids or gases. A sensor body 106 having a cover 108 is attached to the center portion 118. The sensor body 106 also includes a connector 110 with a connector opening 112.

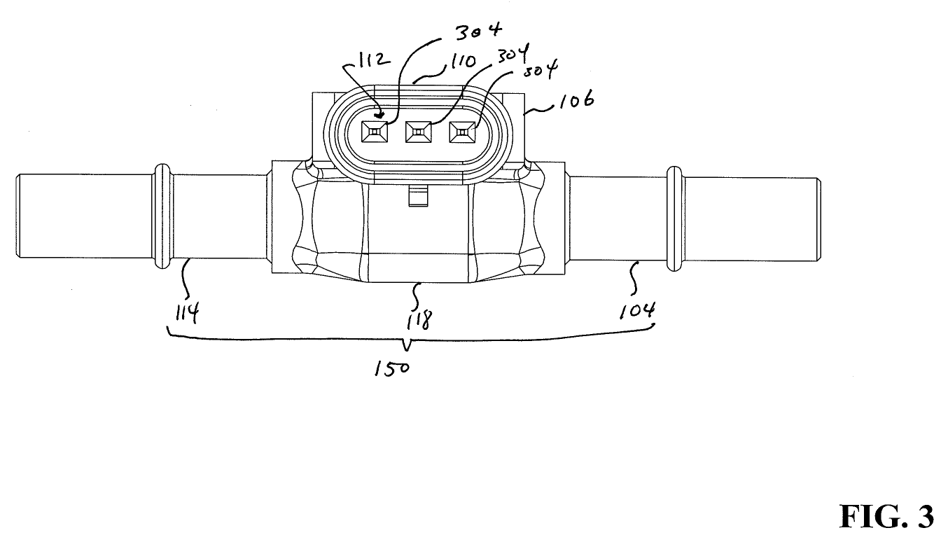

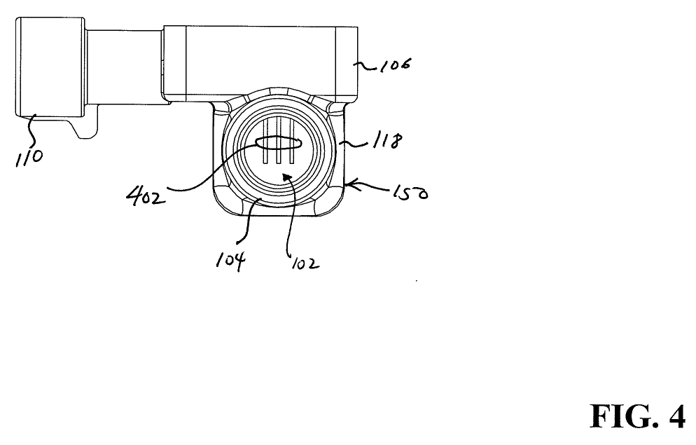

FIG. 3 illustrates a front plan view of the fuel sensor 100 where a plurality of contact pins 304 is accessible through the connector opening 112. FIG. 4 illustrates a side plan view of the fuel sensor 100 where a plurality of pins 402 may be accessible through the tube 104 of the opening 102. As further described herein, the plurality of pins 402 are submerged in the fuel that flows through the fuel tube 150. In one preferred embodiment of the present invention, the length, and the diameter of the plurality of pins 402 can be adjusted to thereby increase or decrease the capacitance pick up as desired.

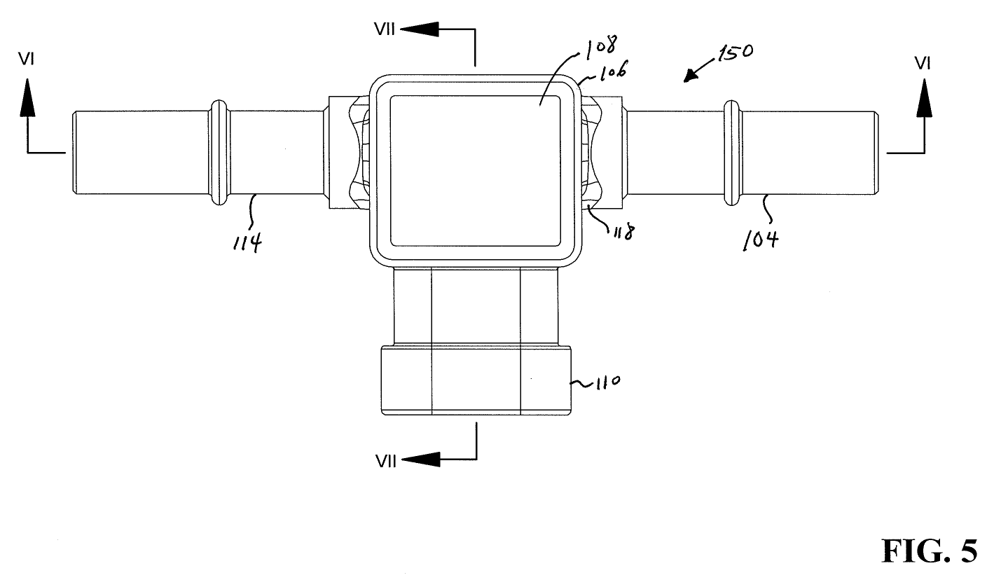

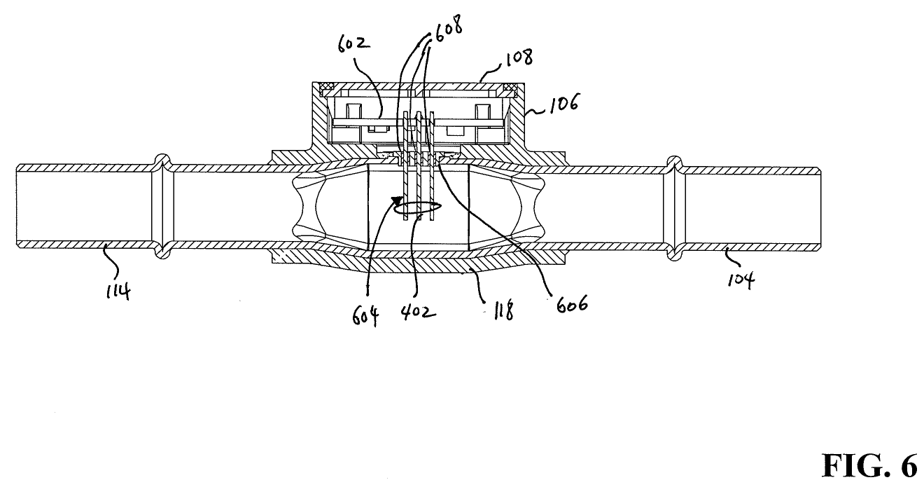

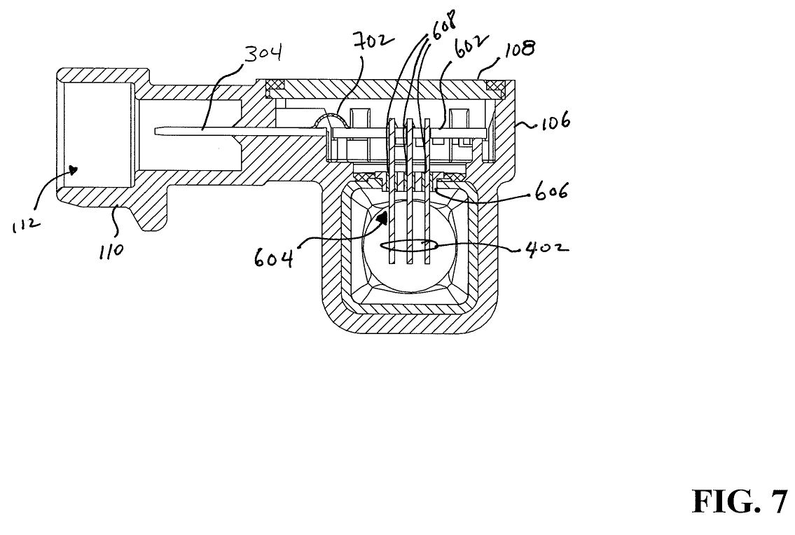

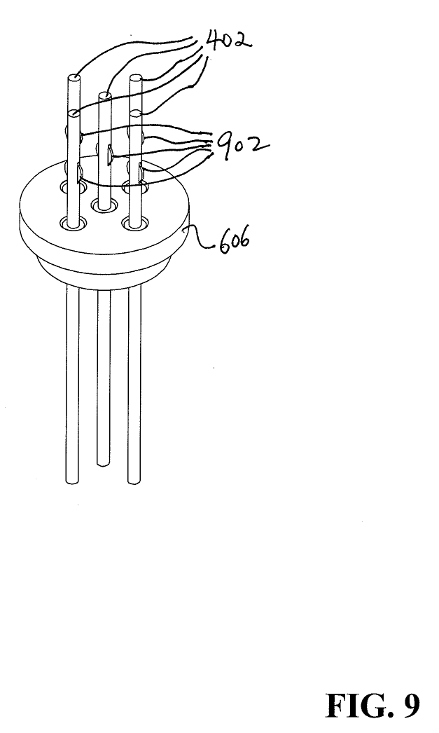

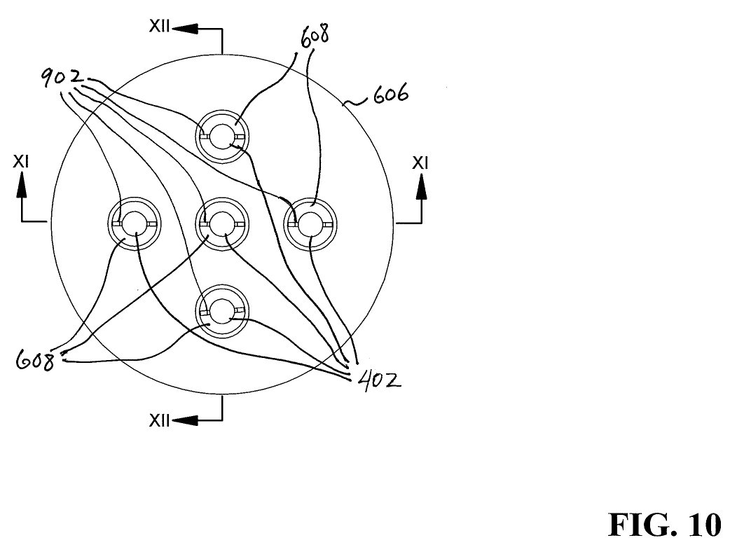

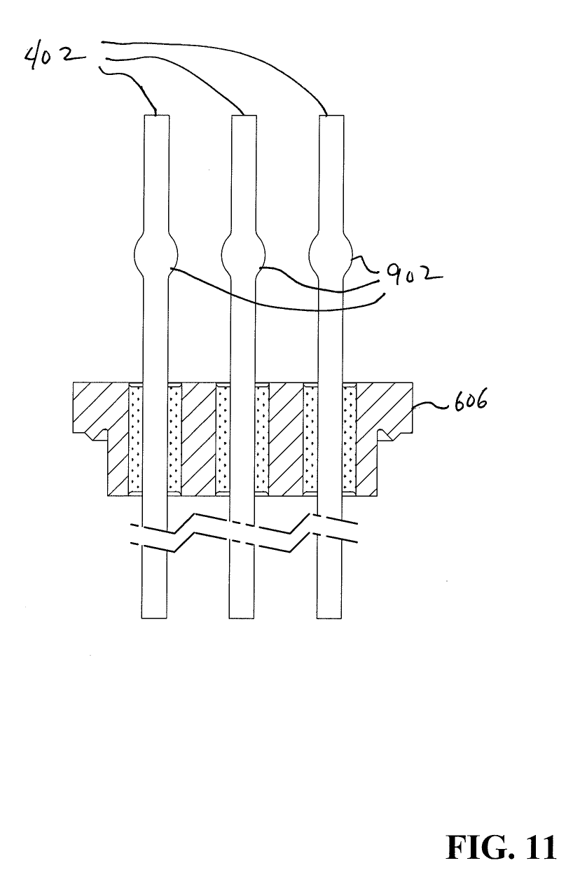

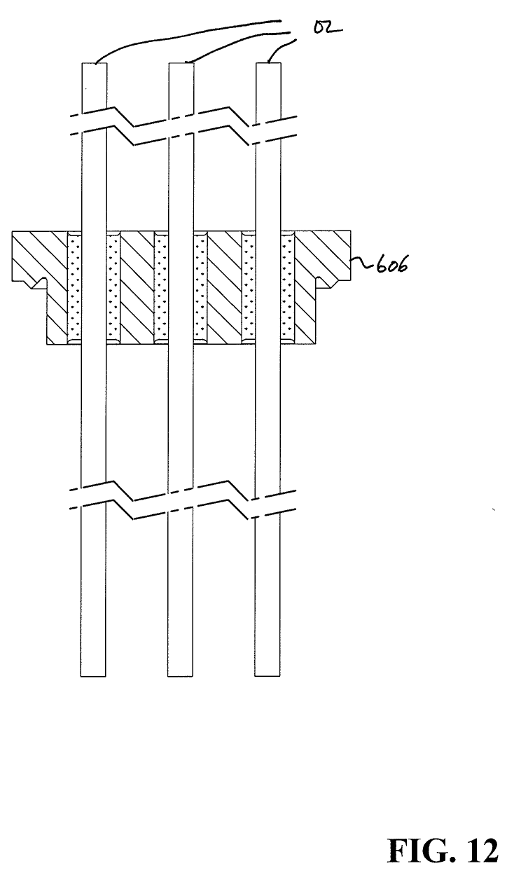

FIG. 5 illustrates a top plan view of the fuel sensor 100 that includes cross-section delineation lines VI-VI and VII-VII that are shown in FIG. 6 and FIG. 7, respectively. In FIG. 6, a header 604 coupled to a circuit board 602 contained in the sensor body 106. The header 604 also includes a header body 606. FIG. 7 illustrates how the plurality of contact pins 304 is attached to circuit board 602 through a plurality of connector wires 702. In one preferred embodiment of the present invention, the header 604 is used as a capacitive probe, where each pin in the plurality of pins 402 functions as an electrode. As illustrated in FIG. 6, as well as FIGS. 9-12, the plurality of pins 402 is attached to header body 606 with a plurality of insulators 608. In one preferred embodiment of the present invention, each pin in the plurality of pins 402 also includes a protruded portion 902 to support the circuit board 602 so that the circuit board 602 will have a place to rest when it is being assembled into fuel sensor 100. In other preferred embodiments of the present invention, each pin in the plurality of pins 402 does not include the protruded portion 902.

In one preferred embodiment of the present invention, the header 604 is a metal, glass, and pin assembly wherein the header body 606 is comprised of metal or composite materials. The metal or composite materials of the header body 606 provides structural support for the header 604. In one preferred embodiment, a material referred to as NiCo 2918, which is a composite comprised of 29% nickel (Ni), 18% cobalt (Co) and 53% iron (Fe), is used. Further, in one preferred embodiment of the present invention, the plurality of insulators 608 is comprised of glass and provides a hermetic seal for and insulation of the plurality of pins 402 from the header body 606. In one preferred embodiment of the present invention, the specific materials are chosen because they provide immunity from corrosion.

Glass-to-metal seals, which are assemblies of glasses with metals that are used to feed electrical conductors through the walls of hermetically-sealed packages, are vacuum tight. They have proven successful in electronic and electrical engineering and cover a wide range of applications in which the sealing glass serves as an excellent insulator. A typical glass-to-metal seal consists of an external metal part into which a pre-formed sintered glass element is sealed. The sintered glass element in turn encloses one or more metal leads that are sealed into it.

In one preferred embodiment, the header 604 performs two fundamental functions: a) acts as a capacitor, and b) provides a hermetic seal. As the fluid (i.e., fuel) passes through the plurality of pins 402 of the header 604, the capacitance measured by the plurality of pins 402 will change in proportion to the dielectric of the fluid. The capacitance signal is then converted through the electronics contained on the circuit board 602 to an output format suitable for the application—which could be a voltage, current, frequency, pulse width modulation (PWM), digital frame, etc.

In one preferred embodiment of the present invention, it is anticipated that the use of a forest of pins for electrodes will at least partially eliminate any sensing errors due to the flow of liquid past the electrodes. There is a wide variety of possible electrode configurations possible and each might have its advantages. For example, an even number of pins in the plurality of pins 402 could be arranged in a circle with alternate pins being opposite electrodes. Or a single central pin could be the “+” electrode and the surrounding pins could all be “−” or ground potential. The surrounding metal structure provided by the header body 606 is grounded and therefore provides an electromagnetic interference (EMI) shield for the electrodes.

In one preferred embodiment of the present invention, large gaps between the plurality of pins 402 and the metal, and the short run of the plurality of pins 402 through the header body 606 (i.e., post height), result in very low parasitic capacitance, which is a highly desirable feature for a capacitive sense element. The gap between the plurality of pins 402 allows fluid to pass through and flow freely without any adverse effect, or restriction. The post height of the header provides for easier mounting of the electronics (PCB, and other circuit materials). Specifically, in one preferred embodiment of the present invention, a smaller post height allows the electronics to be mounted very close to the sense element. Further, a shorter length of the header 604 and the resulting sturdiness keeps the capacitance signal stable (less changing with time) and also provides immunity to vibration.

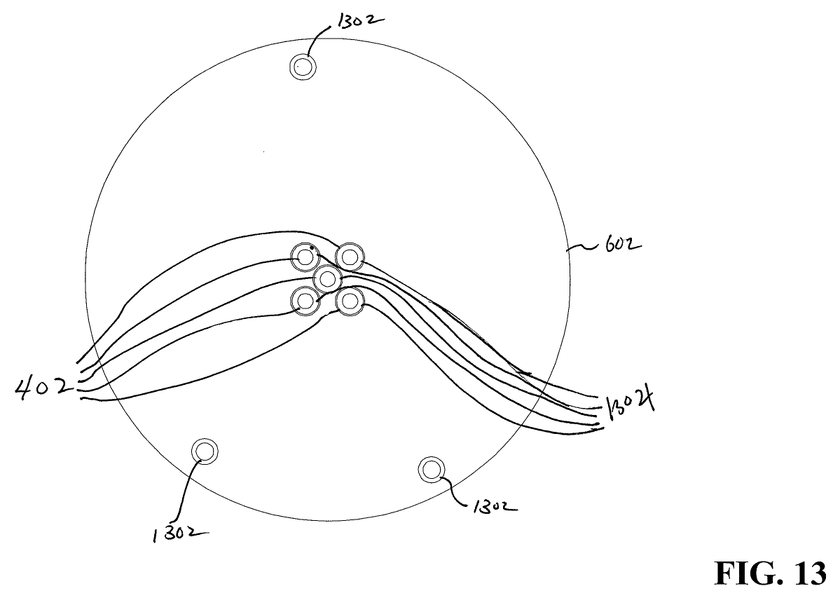

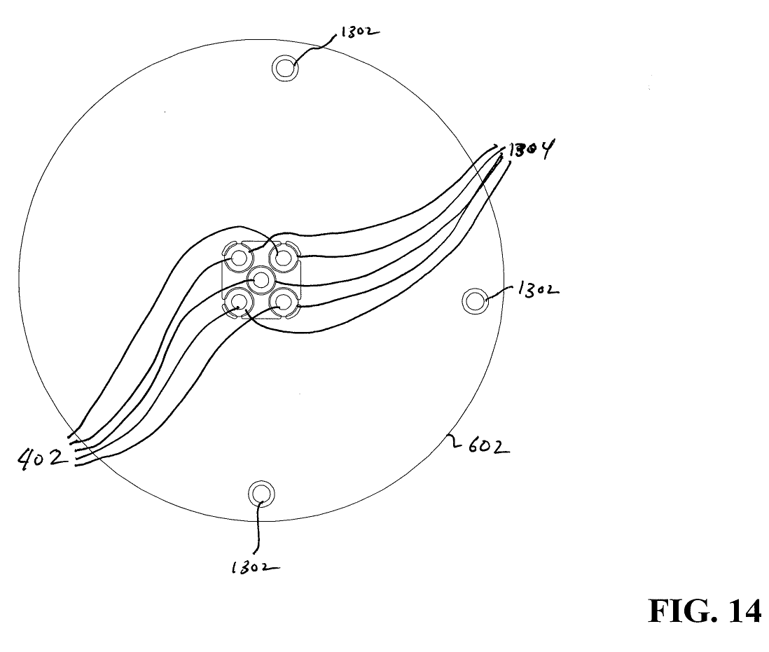

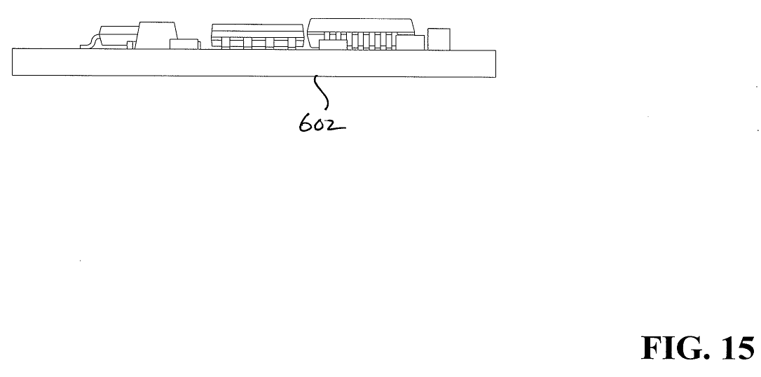

In one preferred embodiment of the present invention, the header 604 is bonded to a structure through brazing, welding, soldering, or any other means that provides “metal-to-metal” seal and maintains the integrity of the seal. The post height (extension on the non fluid side) of each pin of the plurality of pins 402 is used to connect to the electronics on the circuit board 602. As illustrated in FIGS. 13-15, the circuit board 602 include a plurality of openings 1304 so that the plurality of pins 402 pokes through the circuit board 602 so that the plurality of pins 402 may be electrically coupled to the electronics and circuitry on the circuit board 602. The circuit board 602 also includes a plurality of mounting holes 1302 so that the circuit board 602 can be mounted to sensor body 106.

Although the fuel sensor described herein is to be used for flexible fuel based on ethanol, the principles and features disclosed may be applied to other types of fluids where there exists a difference between the DC of the fluid components.

The embodiments described above are exemplary embodiments. Those skilled in the art may now make numerous uses of, and departures from, the above-described embodiments without departing from the inventive concepts disclosed herein. Various modifications to these embodiments may be readily apparent to those skilled in the art, and the generic principles defined herein may be applied to other embodiments, e.g., in fuel production applications, without departing from the spirit or scope of the novel aspects described herein. Thus, the scope of the invention is not intended to be limited to the embodiments shown herein but is to be accorded the widest scope consistent with the principles and novel features disclosed herein. The word “exemplary” is used exclusively herein to mean “serving as an example, instance, or illustration.” Any embodiment described herein as “exemplary” is not necessarily to be construed as the most preferred or advantageous over other embodiments. Accordingly, the present invention is to be defined solely by the scope of the following claims.

What is claimed is:

1. A sensor comprising:
(a) a tube having:
(i) a cavity for holding contents therein; and
(ii) at least one opening in the tube being in communication with the cavity of the tube and the contents held therein; and,
(b) a sensor body attached to the tube, the sensor body having:
(i) a circuit board; and
(ii) a header, the header comprising a plurality of contacts that are electrically coupled to the circuit board;
wherein the plurality of contacts of the header are in communication with the cavity of the tube.

2. The sensor of claim 1, wherein the header is comprised of metal.

3. The sensor of claim 1, wherein the header further comprises an insulative element surrounding at least one contact in the plurality of contacts.

4. The sensor of claim 2, wherein the insulative element is comprised of glass.

5. The sensor of claim 1, wherein the plurality of contacts of the header are electrodes for the header to function as a capacitor with the contents of the tube being treated as a dielectric material.

6. The sensor of claim 1, the header provides a seal between the tube and the sensor housing through a glass-to-metal bond.

7. The sensor of claim 6, wherein the seal between the tube and the sensor housing comprises a hermetic seal.

8. The sensor of claim 1, wherein the header is mounted to the tube through an operation selected from the set consisting of welding, brazing, and soldering.

9. A method for determining the composition of a fluid having a first component and a second component, each component having a respective dielectric property, the method comprising the steps of:
providing a sensor having a capacitative sense element;
putting the fluid in contact with the capacitative sense element;
determining a dielectric property of the fluid based on a capacitance of the capacitative sense element; and,
determining the proportion of at least one of the first component and the second component.

10. The method of claim 9, wherein the step of determining the dielectric property of the fluid based on the capacitance of the capacitative sense element further comprising the steps of:
using the fluid as a dielectric element in the capacitative sense element; and,
measuring a capacitance value of the capacitative sense element.

11. The method of claim 10, wherein the sensor comprising:
(a) a tube having:
(i) a cavity for holding the fluid therein; and
(ii) at least one opening in the tube being in communication with the cavity of the tube and the fluid held therein; and,
(b) a sensor body attached to the tube, the sensor body having:
(i) a circuit board; and
(ii) a header, the header comprising a plurality of contacts that are electrically coupled to the circuit board;
wherein the plurality of contacts of the header are in communication with the fluid in the cavity of the tube.

12. The method of claim 11, wherein the header is comprised of metal.

13. The method of claim 11, wherein the header further comprises an insulative element surrounding at least one contact in the plurality of contacts.

14. The method of claim 13, wherein the insulative element is comprised of glass.

15. The method of claim 11, wherein the plurality of contacts of the header are electrodes for the header to function as a capacitor with the contents of the tube being treated as a dielectric material.

16. The method of claim 11, the header provides a seal between the tube and the sensor housing through a glass-to-metal bond.

17. The method of claim 16, wherein the seal between the tube and the sensor housing comprises a hermetic seal.

18. The method of claim 11, wherein the header is mounted to the tube through an operation selected from the set consisting of welding, brazing, and soldering.

19. An apparatus for determining the composition of a fluid having a first component and a second component, each component having a respective dielectric property, comprising:
a container for holding the fluid;
a capacitative sense element, the capacitative sense element having a plurality of electrodes placed in contact with the fluid in the container; and,
a circuit coupled to the capacitative sense element, the circuit configured to determine a dielectric property of the fluid based on a capacitance of the capacitative sense element.

20. The apparatus of claim 19, the capacitative sense element comprising a header, the header having an insulative element surrounding at least one electrode in the plurality of electrodes.

21. The apparatus of claim 20, wherein the header is comprised of metal.

22. The apparatus of claim 20, wherein the insulative element is comprised of glass.
